(19) United States
(12) Patent Application Publication
(10) Pub. No.: US 2004/0242004 A1
(43) Pub. Date: Dec. 2, 2004

(54) Substrate treating method and apparatus

(75) Inventors: Hajime Shirakawa, Horikawa-dori (JP); Hiroaki Uchida, Horikawa-dori (JP); Akira Morita, Korikawa-dori (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/807,052

(22) Filed: Mar. 23, 2004

(30) Foreign Application Priority Data
Mar. 24, 2003 (JP) 2003-080369

(51) Int. Cl. B05D 1/00; B05D 5/00; H01L 21/302; H01L 21/461

(52) U.S. Cl. 438/691

(57) ABSTRACT

A substrate treating method for performing a predetermined treatment of substrates as immersed in a treating liquid stored in a treating tank. The method includes a first step of deriving a current treating rate from a relationship between use history and treating rate of the treating liquid and an up-to-date use history of the treating liquid, a second step of determining a corrected treating time by extending a predetermined treating time according to the current treating rate, and a third step of treating the substrates for the corrected treating time.

### BACKGROUND OF THE INVENTION

(1) Field of the Invention

This invention relates to a substrate treating method and substrate treating apparatus for performing a predetermined treatment for cleaning, etching or otherwise treating semiconductor wafers, glass substrates for photomasks, glass substrates for liquid crystal displays, substrates for optical disks and so on (hereinafter called simply substrates). More particularly, the invention relates to a technique for performing treatment of substrates as immersed in a treating liquid stored in a treating tank.

(2) Description of the Related Art

A conventional method of this type is carried out, for example, with an apparatus having an inner tank for storing the treating liquid, an outer tank for collecting the treating liquid overflowing the inner tank, piping interconnecting the inner tank and outer tank, and a heater for heating the treating liquid in circulation to a high temperature (see Japanese Unexamined Patent Publication No. 9-181041 (1997), for example).

In this method, for example, heated phosphoric acid (H₃PO₄) is stored in a treating tank, and substrates coated with nitride film are immersed in the phosphoric acid for a predetermined time for treatment.

The conventional method noted above has the following drawback.

Phosphoric acid deteriorates through use, and its etching rate lowers at the same time. Generally, therefore, the number of lots, use time and so on are closely observed, and the phosphoric acid is replaced with a fresh portion when the number or time reaches a limit.

In etching treatment by phosphoric acid in particular, only several lots can be processed in reality since the device technology requires a strictly precise thickness, and also uniformity, of the nitride film to be left on substrates. Thus, phosphoric acid must be changed frequently, and hence a heavy consumption of phosphoric acid.

It is conceivable to adding supplements of phosphoric acid, instead of changing to a fresh portion of phosphoric acid, to return the etching rate close to what is expected from the fresh portion. However, even if the concentration is the same as the fresh portion, it is not realistic to recover the etching rate by adding phosphoric acid since the etching rate depends on the concentration of polysiloxane (silicic compound) in the phosphoric acid.

This invention has been made having regard to the state of the art noted above, and its object is to provide a substrate treating method and apparatus capable of reducing the frequency of changing a treating liquid while maintaining proper treatment, by adjusting treating time according to a degree of deterioration of the treating liquid.

### SUMMARY OF THE INVENTION

The above object is fulfilled, according to this invention, by a substrate treating method for performing a predetermined treatment of substrates as immersed in a treating liquid stored in a treating tank, comprising:

a first step of deriving a current treating rate from a relationship between use history and treating rate of the treating liquid and an up-to-date use history of the treating liquid;

a second step of determining a corrected treating time by extending a predetermined treating time according to the current treating rate; and

a third step of treating the substrates for the corrected treating time.

A current treating rate by the treating liquid is derived from an up-to-date use history of the treating liquid and a relationship between use history and treating rate of the treating liquid (first step). A corrected treating time is determined by extending a predetermined treating time according to the current treating rate (which has been reduced from the time of a fresh portion of the treating liquid) (second step). The substrates are treated for the corrected treating time (third step). Thus, a predetermined treatment such as cleaning or etching is carried out properly even with the treating liquid having deteriorated. There is no need for changing the treating liquid simply because treatment has been carried out a predetermined number of times or for a predetermined number of substrates. The treating liquid is changed less frequently than in the prior art.

In this invention, the first step, preferably, is executed by taking into account at least one of a treated number of substrates, a treating rate, a treating time, a substrate type, a rate of over-treatment, a substrate coverage of film and an initial treating rate.

The use history indicative of a degree of deterioration of the treating liquid is variable with a treated number of substrates, a treating rate, a treating time and so on. Thus, a current treating rate may be determined with high accuracy by taking at least one of these parameters into account.

The above treating rate refers to an etching rate or cleaning rate, and the substrate type to a substrate size or shape. The rate of over-treatment concerns, for example, an extent of further etching to be made after etching a predetermined film thickness.

Of the above parameters, what are most desirable to be considered are the treated number of substrates, treating time and substrate coverage of film.

According to another aspect of the invention, a substrate treating apparatus is provided for performing a predetermined treatment of substrates as immersed in a treating liquid stored in a treating tank. This apparatus comprises:

a storage device for storing a relationship between use history and treating rate of the treating liquid and an up-to-date use history of the treating liquid;

a calculating device for deriving a current treating rate from the relationship between use history and treating rate of the treating liquid and the up-to-date use history of the treating liquid; and

a computing device for determining a corrected treating time by extending a predetermined treating time according to the current treating rate;

wherein the substrates are treated for the corrected treating time.

The calculating device derives a current treating rate from the up-to-date use history of the treating liquid stored in the storage device and the relationship between use history and treating rate of the treating liquid stored in the storage device. The computing device determines a corrected treating time by extending a predetermined treating time according to the current treating rate. The substrates are treated for the corrected treating time, whereby the treatment is carried out properly even with the treating liquid having deteriorated. In this way, the apparatus can effectively implement the method according to this invention, to reduce the frequency of changing the treating liquid compared with the prior art.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a block diagram showing an outline of a substrate treating apparatus according to the invention;

FIG. 2 is a graph showing an example of data of use history and etching rate; and

FIG. 3 is a flow chart showing an operation of etching treatment.

### DESCRIPTION OF THE PREFERRED EMBODIMENT

A preferred embodiment of this invention will be described in detail hereinafter with reference to the drawings.

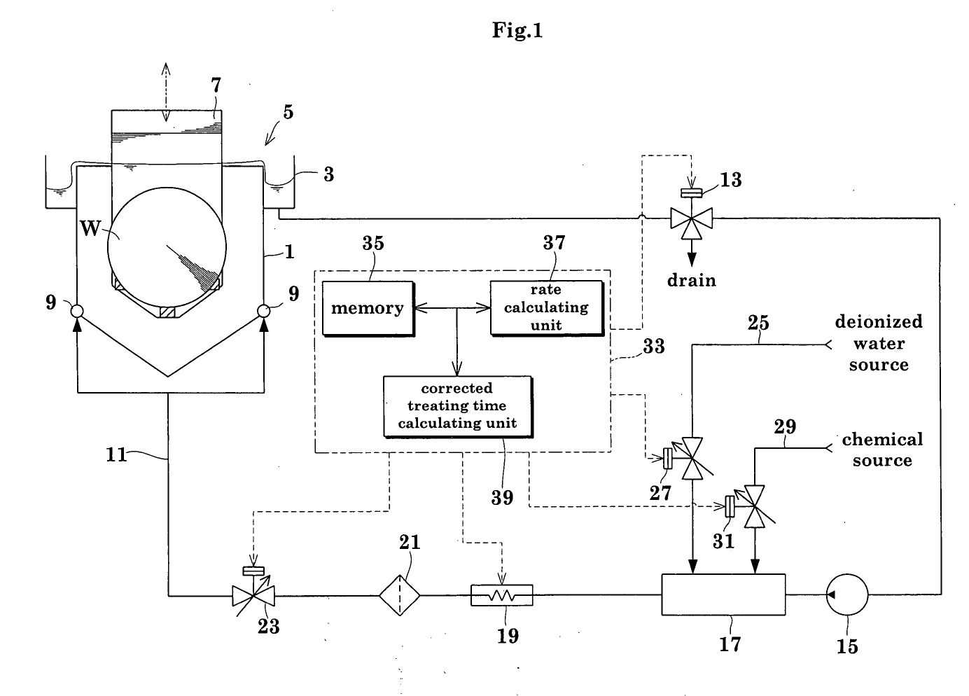

FIG. 1 is a block diagram showing an outline of a substrate treating apparatus in one embodiment of the invention

This substrate treating apparatus is what is known as a batch type treating apparatus for treating a plurality of wafers W at one operation. The apparatus includes a treating tank 5 having an inner tank 1 for storing a treating liquid, and an outer tank 3 for collecting the treating liquid overflowing the inner tank 1. The inner tank 1 is associated with a holding arm 7 vertically movable, while holding a plurality of wafers W in vertical posture, between a treating position shown in FIG. 1 and a standby position above the inner tank 1.

The inner tank 1 has injection pipes 9 disposed adjacent the bottom thereof for supplying the treating liquid into the inner tank 9. The injection pipes 9 are connected to the outer tank 3 by treating liquid piping 11. This substrate treating apparatus is the treating liquid circulating type.

The treating liquid piping 11 includes a three-way valve 13, a circulating pump 15, a mixing valve 17, an in-line heater 19, a filter 21 and a flow control valve 23 arranged in order from the outer tank 3, i.e. from an upstream end in the flowing direction of the treating liquid.

The three-way valve 13 is switchable to circulate the treating liquid from the outer tank 3 through the treating liquid piping 11 or to discharge and drain the treating liquid. The circulating pump 15 delivers the treating liquid in the treating liquid piping 11 to the inner tank 1. The mixing valve 17 has water piping 25 connected thereto through a control valve 27 and communicating with a deionized water source. The mixing valve 17 has also chemical piping 29 connected thereto through a control valve 31 and communicating with a chemical source. In this embodiment, the chemical source stores “phosphoric acid” (H₃PO₄).

The in-line heater 19 heats the treating liquid circulating through the treating liquid piping 11 to a predetermined temperature. The filter 21 removes particles and the like from the treating liquid. The flow control valve 23 controls the flow rate of the treating liquid circulating through the treating liquid piping 11. The treating liquid in this example is phosphoric acid or deionized water.

The holding arm 7, three-way valve 13, circulating pump 15, in-line heater 19, flow control valve 23 and control valves 27 and 31 are controlled en bloc by a controller 33.

The controller 33 has a CPU not shown, a memory unit 35, a rate calculating unit 37 and a corrected treating time calculating unit 39.

The memory unit 35 which corresponds to the storage device in this invention stores a “recipe” specifying a treating procedure for the wafers W, “data” showing a relationship between use history and etching rate of the treating liquid, and “use history” of the treating liquid currently stored in the tank 1 which is updated at appropriate times.

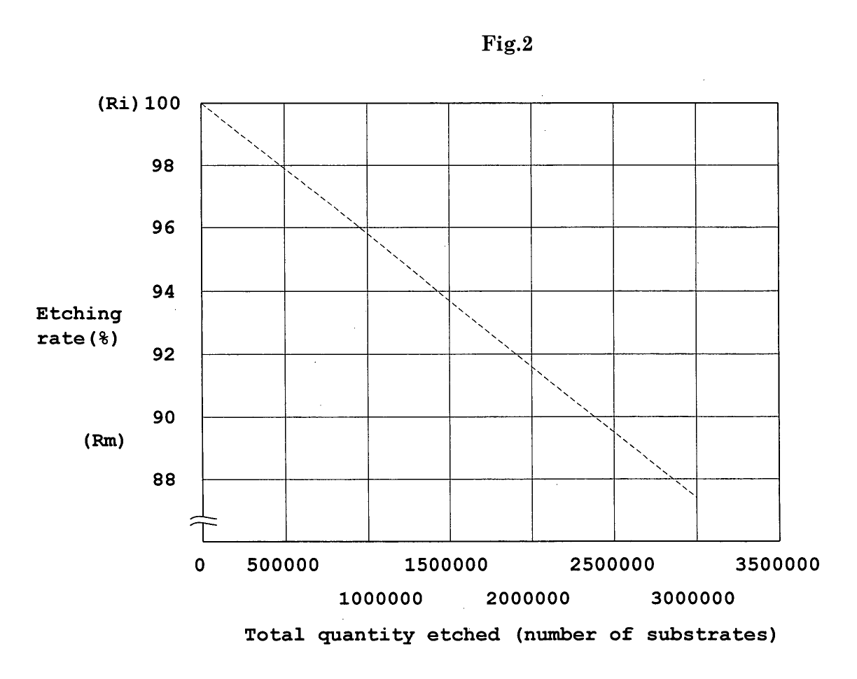

Reference is now made to FIG. 2.

FIG. 2 is a graph showing an example of data of use history and etching rate. While plotting points are omitted from this graph, wafers W coated with nitride film were immersed in the same phosphoric acid for a fixed time, a film thickness was measured after each treating operation to determine an etching rate, and the dotted line was drawn to show a correlation thereof. The vertical axis in the graph represents normalized etching rates, with 100 (%) indicating an etching rate by a fresh portion of phosphoric acid. The horizontal axis in the graph represents total quantities etched, i.e. numbers of wafers W treated.

In etching treatment of nitride film by phosphoric acid, polysiloxane (silicic compound) which is a product resulting from etching increases in the phosphoric acid. This lowers the etching capability of the phosphoric acid. That is, the etching rate lowers. The degree of lowering is dependent on the concentration of polysiloxane in the phosphoric acid. However, it is difficult to measure the polysiloxane concentration.

The memory unit 35 may store a calibration curve such as the above graph as data, or an equation of the line in the graph as data.

The rate calculating unit 37 which corresponds to the calculating device in this invention reads, prior to treatment, the use history of the current treating liquid from the memory unit 35 to determine a degree of deterioration of the current treating liquid. Specifically, a current etching rate of the current treating liquid is derived from the above data and use history.

The corrected treating time calculating unit 39 which corresponds to the computing device in this invention refers to the recipe stored in the memory unit 35, and reads an etching time included in the recipe. The corrected treating time calculating unit 39 extends the etching time according to the current etching rate, and determines a corrected etching time.

The corrected etching time is determined as follows, for example:

corrected etching time A1(min)=Ti·(Ri/Rm) (1)

where Ti (nm/min) is the etching time specified in the recipe with reference to a fresh treating liquid, Ri (nm/min) is an etching rate of the fresh treating liquid, and Rm (nm/min) is the current etching rate.

When, for example, the treating liquid has deteriorated and the current etching rate Rm is one half of the etching rate Ri by the fresh treating liquid, the etching time Ti is multiplied by the inverse. By making the etching time Ti twice as long, the treating liquid having deteriorated can attain the same etching quantity as the fresh treating solution.

After the corrected treating time calculating unit 39 determines the corrected etching time A1, the controller 33 moves the holding arm 7 holding the wafers W into the inner tank 1. The wafers W are maintained in the inner tank 1 for the corrected etching time A1.

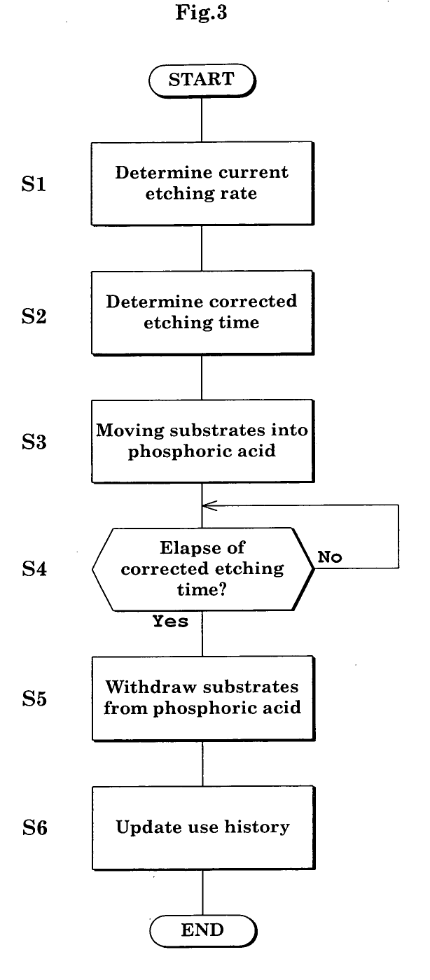

Next, an operation of the above substrate treating apparatus will be described with reference to FIG. 3. FIG. 3 is a flow chart showing an operation of etching treatment.

It is assumed here that wafers W are already held by the holding arm 7 in the standby position, and that the inner tank 1 stores phosphoric acid that has already deteriorated to a certain extent through use. It is assumed also that the use history of the current treating liquid is stored in the memory unit 35. Furthermore, the phosphoric acid which is the treating liquid has already been heated to the temperature specified in the recipe, and is in circulation.

Step S1

The rate calculating unit 37 refers to the use history in the memory unit 35, and derives the current etching rate Rm from the data in the memory unit 35.

Step S2

The corrected treating time calculating unit 39 determines the corrected etching time A1 by substituting into the above equation (1) the current etching rate Rm and the etching time Ti specified in the recipe stored in the memory unit 35. When the data has been normalized, “1” (or 100%) may be used as the etching rate Ri for the treating liquid being a fresh portion.

Step S3

The controller 33 moves the holding arm 7 from the standby position to the treating position shown in FIG. 1, to dip the wafers W into the phosphoric acid in the inner tank 1.

Step S4

The controller 33 starts counting upon completion of the movement to the treating position in Step S3. The existing state is maintained until the above corrected etching time A1 is reached. When the corrected etching time A1 is reached, the operation proceeds to step S5. As noted hereinbefore, the etching treatment results in an increase of polysiloxane in the current phosphoric acid, and a lowering of the etching rate.

Step S5

When the corrected etching time A1 is reached, the controller 33 moves the holding arm 7 to the standby position above the treating position shown in FIG. 1. This completes the etching treatment of the wafers W. The wafers W are transferred to a separate transport mechanism not shown, to undergo rinsing and drying processes successively.

Step S6

After the etching treatment, the controller 33 updates the use history stored by the memory unit 35. The updating is effected based on the number of wafers W.

The wafers W are etched through the above series of treating steps. An etching rate by the current phosphoric acid is derived from the data showing the up-to-date use history of the phosphoric acid and the relationship between the use history and etching rate of the phosphoric acid. A corrected etching time is determined by extending the etching time specified in the recipe according to the etching rate determined. The wafers W are treated for the corrected etching time, whereby the treatment is carried out properly even with the phosphoric acid having deteriorated. There is no need for changing the phosphoric acid simply because treatment has been carried out a predetermined number of times or for a predetermined number of wafers W. The treating liquid is changed less frequently than in the prior art.

This invention is not limited to the foregoing embodiment, but may be modified as follows:

(1) The use history is not limited to a treated number of substrates, but may be determined by taking into account at least one of the following parameters: a treating rate according to a treating liquid concentration, a treating time such as etching time or cleaning time, the type of substrates such as a size or outer shape of substrates, an over-treating rate indicating an extent of excess treatment, a substrate coverage of film formed on substrates, and a rate of treatment.

Of the above parameters, the most important and easy to determine a correlation with deterioration are the treated number of substrates, treating time, and substrate coverage of film.

(2) The forgoing embodiment has been described by taking etching treatment with phosphoric acid for example. The invention is applicable also to etching treatment with hydrofluoric acid or other treating liquid, and to cleaning treatment a treating liquid such as sulfuric acid.

This invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method for performing a predetermined treatment of substrates as immersed in a treating liquid stored in a treating tank, comprising:
a first step of deriving a current treating rate from a relationship between use history and treating rate of the treating liquid and an up-to-date use history of the treating liquid;
a second step of determining a corrected treating time by extending a predetermined treating time according to said current treating rate; and
a third step of treating the substrates for said corrected treating time.

2. A method as defined in claim 1, wherein said first step is executed by taking into account at least one of a treated number of substrates, a treating rate, a treating time, a substrate type, a rate of over-treatment, a substrate coverage of film and an initial treating rate.

3. A method as defined in claim 1, wherein said first step is executed by taking into account at least one of a treated number of substrates, a treating time and a substrate coverage of film.

4. A method as defined in claim 1, wherein said corrected treating time is derived from;
A1=Ti·(Ri/Rm)
where Ti is an etching time specified in a recipe with reference to a fresh portion of said treating liquid, Ri is an etching rate of the fresh portion, and Rm is the current etching rate.

5. A method as defined in claim 2, wherein said corrected treating time is derived from;
A1=Ti·(Ri/Rm)
where Ti is an etching time specified in a recipe with reference to a fresh portion of said treating liquid, Ri is an etching rate of the fresh portion, and Rm is the current etching rate.

6. A method as defined in claim 3, wherein said corrected treating time is derived from;
A1=Ti·(Ri/Rm)
where Ti is an etching time specified in a recipe with reference to a fresh portion of said treating liquid, Ri is an etching rate of the fresh portion, and Rm is the current etching rate.

7. A method as defined in claim 1, wherein said treating liquid includes phosphoric acid.

8. A method as defined in claim 2, wherein said treating liquid includes phosphoric acid.

9. A method as defined in claim 4, wherein said treating liquid includes phosphoric acid.

10. A method as defined in claim 1, wherein said treating liquid includes hydrofluoric acid.

11. A substrate treating apparatus for performing a predetermined treatment of substrates as immersed in a treating liquid stored in a treating tank, comprising:
storage means for storing a relationship between use history and treating rate of the treating liquid and an up-to-date use history of the treating liquid;
calculating means for deriving a current treating rate from said relationship between use history and treating rate of the treating liquid and said up-to-date use history of the treating liquid; and
computing means for determining a corrected treating time by extending a predetermined treating time according to said current treating rate;
wherein said substrates are treated for said corrected treating time.

12. A apparatus as defined in claim 11, wherein said calculating means is arranged to take into account at least one of a treated number of substrates, a treating rate, a treating time, a substrate type, a rate of over-treatment, a substrate coverage of film and an initial treating rate.

13. A apparatus as defined in claim 11, wherein said calculating means is arranged to take into account at least one of a treated number of substrates, a treating time and a substrate coverage of film.

14. A apparatus as defined in claim 11, wherein said calculating means is arranged to derive said corrected treating time from;
A1=Ti·(Ri/Rm)
where Ti is an etching time specified in a recipe with reference to a fresh portion of said treating liquid, Ri is an etching rate of the fresh portion, and Rm is the current etching rate.

15. A apparatus as defined in claim 12, wherein said calculating means is arranged to derive said corrected treating time from;
A1=Ti·(Ri/Rm)
where Ti is an etching time specified in a recipe with reference to a fresh portion of said treating liquid, Ri is an etching rate of the fresh portion, and Rm is the current etching rate.

16. A apparatus as defined in claim 13, wherein said calculating means is arranged to derive said corrected treating time from;
A1=Ti·(Ri/Rm)
where Ti is an etching time specified in a recipe with reference to a fresh portion of said treating liquid, Ri is an etching rate of the fresh portion, and Rm is the current etching rate.

17. A apparatus as defined in claim 11, wherein said treating liquid includes phosphoric acid.

18. A apparatus as defined in claim 12, wherein said treating liquid includes phosphoric acid.

19. A apparatus as defined in claim 14, wherein said treating liquid includes phosphoric acid.

20. A apparatus as defined in claim 11, wherein said treating liquid includes hydrofluoric acid.
